(19) United States
(12) Patent Application Publication
(10) Pub. No.: US 2013/0135712 A1
(43) Pub. Date: May 30, 2013

(54) YTTRIUM OXIDE COATED OPTICAL ELEMENTS WITH IMPROVED MID-INFRARED PERFORMANCE

(71) Applicants: Horst Schreiber, Corning, NY (US); Jue Wang, Fairport, NY (US); Scott J. Wilkinson, Shrewsbury, MA (US)

(72) Inventors: Horst Schreiber, Corning, NY (US); Jue Wang, Fairport, NY (US); Scott J. Wilkinson, Shrewsbury, MA (US)

(21) Appl. No.: 13/687,473

(22) Filed: Nov. 28, 2012

Related U.S. Application Data
(60) Provisional application No. 61/564,367, filed on Nov. 29, 2011.

(51) Int. Cl. C23C 16/40; G02B 27/00

(52) U.S. Cl. CPC C23C 16/405; G02B 27/00
USPC 359/350; 427/539

(57) ABSTRACT

The disclosure is directed to a method of making yttrium oxide, Y₂O₃, coatings on substrates suitable for use at infrared wavelengths, including use in the 2-12 μm range. The coating method eliminates or substantially eliminates the absorptions peaks that typically appear at approximately 3.0 μm, 6.6 μm and 7.1 μm. This is achieved by using Y metal as the yttrium source in combination with an oxygen-containing plasma to form the Y₂O₃, coating in place of the using Y₂O₃ as the coating material source The disclosure is further directed to optics suitable for use in the infrared that have such coatings. The transmission spectrum of the coated substrate made according to the method described herein is greater than the transmission spectrum of the uncoated substrate over the wavelength range of 4 μm to 12 μm.

This application claims the benefit of priority under 35 U.S.C. §119 of U.S. Provisional Application Ser. No. 61/564,367 filed on Nov. 29, 2011 the content of which is relied upon and incorporated herein by reference in its entirety.

### FIELD

The disclosure is directed to yttrium oxide coatings having improved performance in the mid-infrared region, and in particular to yttrium oxide coatings in which the yttrium oxide coating's absorption peaks at 3 μm, 6.6 μm and 7.1 μm are eliminated.

### BACKGROUND

Metal oxides are the materials of choice for the production of optical interference coatings in the visible and ultraviolet spectral ranges due to their excellent properties such as optical transparency and environmental stability. However, in the infrared (IR) spectral range, metal oxides are not widely used because these materials are not absorption free throughout the IR range of approximately 0.75 μm to 12 μm. Yttrium oxide is one of the more attractive metal oxides for IR oxide coatings and although it has relatively high transmittance up to the long-wave infrared (LWIR) range, it is not entirely absorption free. The attractive properties of yttrium oxide (Y₂O₃) are good thermal and chemical stability, and high mechanical strength and hardness when compared to other IR materials such as ZnSe and ZnS. Yttrium oxide coatings could thus be used in a variety of processes such as protecting a semiconductor processing apparatus (U.S. Patent Application Publication No. 2005/0037193); as a fiber reinforced coating (U.S. Pat. No. 5,316,797); as a diffusion barrier coating in glass molding processes (U.S. Pat. No. 5,769,918); as an antireflective coating for solar cells (U.S. Pat. No. 4,246,043); and as an antireflective and protective coating for infrared optics using ZnSe or ZnS (Su Xianjum et al, “Design and Fabrication of antireflection coating on ZnS substrates,” Proceeding SPIE, Vol 6149, 614907 (2006). However, as stated above, in IR optical applications Y₂O₃ coating are not completely absorption free. For example, Su Xiangjun, ibid, and Rongfa Chen, “Investigation of infrared transmittivity [sic] of Y₂O₃ coating/diamond films,” Chinese Optics Letters, Vol. 8 Supplement, pages 130-133 (2010), reported that coatings made using electron beam (e-beam) evaporated Y₂O₃ exhibit several IR absorption bands located at approximately 3.0 μm, 6.6 μm and 7.1 μm. These coatings were prepared by the usual prior art method in which Y₂O₃, in the form of a compressed disc of material was electron bean evaporated and deposited on a substrate. This method give rise to the adsorption peaks at approximately 3.0 μm, 6.6 μm and 7.1 μm. Consequently, in order to make full use of the desirable properties of yttrium oxide coatings over a broader range, particularly in the approximately 3-8 μm range, there is a need for improving the transmittance of Y₂O₃ films or coatings.

### SUMMARY

The present disclosure is directed to improved, low transmission loss yttrium oxide coatings made using a modified reactive plasma ion-assisted deposition (PIAD) and optics having such coating thereon and to optical elements having such coatings. The method for making optical elements having a yttrium oxide thereon utilizes plasma ion-assisted deposition, an oxygen ion-containing atmosphere during deposition and yttrium metal as the yttrium source. Using this method it has been found that the three typical absorption band peaks at approximately 3 μm, 6.6 μm and 7.1 μm are eliminated or substantially eliminated in IR spectral region of approximately 2-12 μm and a homogeneous Y₂O₃ coating was formed on the substrate. Samples prepared using ZnSe as a substrate and a Y₂O₃ coating having a thickness of 990 μm exhibited at least 70% transmittance in the spectral range of 2-12 μm. The Y₂O₃ coating according to the disclosure can be used in numerous IR applications in which low absorption loss Y₂O₃ coatings are desired; for example, as protective coatings for Ag and Au mirrors, protective antireflection coatings for substrates, for example without limitation, ZnSe and ZnS, and in other applications in which Y₂O₃ coatings are desirable and useful. The advantages of the present disclosure are as follows.
1. Yttrium metal was used as a starting material instead of yttrium oxide, which ensures a stable deposition rate and enables thick layer deposition of Y₂O₃ for IR applications.
2. Dense, homogeneous and smooth Y₂O₃ coatings were obtained via modified reactive plasma ion-assisted deposition.
3. The three absorption peaks at approximately 3.0 μm, 6.6 μm and 7.1 μm in Y₂O₃ coatings are eliminated by using modified reactive plasma ion-assisted deposition.
4. The derived Y₂O₃ coating can be used for optical coating for the SWIR, MWIR and LWIR ranges.
5. The low loss Y₂O₃ films or coatings according to the present disclosure can be used as a protective coating in many different IR application, for example as protective coating for Ag and Au mirrors, and as a protective antireflection coating for ZnSe and ZnS substrates.

In one embodiment the yttrium oxide coating does not decrease the transmittance and the overall transmission is greater than or equal to the uncoated substrate.

### BRIEF DESCRIPTION OF THE DRAWINGS

FIG. 1 is a graph comparing the IR transmittance in the 2-12 μm range of an uncoated ZnSe substrate and a ZnSe substrate having a Y₂O₃ coating on one side, the coating being applied by the traditional method of evaporating Y₂O₃.

FIG. 2 is a graph comparing the IR transmittance in the 2-12 μm range of an uncoated ZnSe substrate and a ZnSe substrate having a Y₂O₃ coating on one side, the coating being applied using the PIAD method and the materials as described herein, including the evaporation of yttrium metal and the use of an oxygen containing plasma.

FIG. 3 is a graph illustrating the refractive index profile at a wavelength of 9 μm of a 990 nm thick Y₂O₃ coating on a ZnSe substrate, the coating being made using the PIAD method described herein.

FIG. 4 is a white light interferometry image of a 990 nm thick coating on a ZnSe substrate, the coating being made using the PIAD method described herein.

FIG. 5 is a slope map of the white light image of FIG. 4 that clearly shows surface polish structures that are transferred fro the ZnSe substrate to the 990 mm-thick Y₂O₃ surface which indicates a dense and homogeneous film or coating process.

FIG. 6 is a schematic drawing illustrating the general set-up for depositing the Y₂O₃ coatings, including the use of the reverse mask 44, a metallic yttrium target 42 that is bombarded by an e-beam 40 and an O₂ bleed 48 into the plasma 47 generated by source 46.

### DETAILED DESCRIPTION

Herein, the Y₂O₃ coatings referred to as “prior art” coatings are those made using Y₂O₃ as the coating material source and not yttrium metal, Y, as described in the present disclosure, and the deposition was carried out using electron beam deposition methods in which the Y₂O₃ source material is vaporized and deposited on a substrate without the use of any plasma ion assistance. In contrast to the prior art, the Y₂O₃ coatings of this disclosure are made using Y metal as the Y source 42. The Y metal is vaporized by the e-beam, is oxidized upon contact with the oxygen 48 fed into the plasma 47 and forms a Y₂O₃ coating on deposition onto a substrate 62. Also herein the terms “substrate” and “optic” may be used interchangeably; and the terms “coated substrate” and “coated optic” may also be used interchangeably.”

Oxide materials are widely used in optical coating technology because of their excellent optical, thermal and mechanical properties when compared to fluoride materials and to II-VI semiconductors such ZnSe and ZnS. However, the spectral bandwidth of oxide coatings is restricted by two fundamental absorption edges located in ultraviolet (UV) and infrared (IR) spectral regions, respectively. The UV absorption edge represents inter-band electron excitation, whereas the IR absorption edge corresponds to phonon and intra-band electron excitation. The spectral coverage of oxide coatings for optical applications ranges from UV to near IR. As a result, fluorides and II-VI semiconductors such ZnSe and ZnS are dominated in the IR spectral region. However, due to soft nature of these IR materials, it is desirable to extend the range of oxide coatings for optical applications from the near IR (NIR, approximately 0.75-1.4 μm) to short-wavelength IR (SWIR, 1-3 μm) and middle-wave infrared (MWIR, 3-5 μm), and even long-wave infrared (LWIR, 8-14 μm).

Infrared sensors for imaging are used extensively for both civilian and military purposes. Civilian uses include infrared astronomy using a sensor equipped telescope to penetrate space dust to detect objects such as planets and view red-shifted objects, thermal efficiency analysis, environmental monitoring, industrial facility inspections, remote temperature sensing, short-ranged wireless communications, spectroscopy and weather forecasting. Military applications include target acquisition, surveillance, night vision, homing and tracking. These uses require that the sensors have a coating that can withstand environmental conditions both terrestrial and extra-terrestrial that would degrade an uncoated sensor's performance.

Among various oxide materials, yttrium oxide (Y₂O₃) is one of the best candidates as oxide coating material for the expanded IR applications due to its excellent optical, thermal and mechanical properties. The Background section provides several citations directed to various applications of yttrium oxide as a coating material. These citations indicate that there are some strong absorptions appearing in the IR spectral regions that lead to high absorption losses. In particular there are large losses at 3.0 μm, 6.6 μm and 7.1 μm. In addition, Chen et al, op cit., found that Y₂O₃ coatings have an inhomogeneous structure. An inhomogeneous coating structure can reduce the coating durability and increase scatter loss. As a result, there are two technical challenges that must be overcome in order to extend Y₂O₃ coatings into the short wavelength and mid-wavelength IR regions. These challenges are:

(a) reducing Y₂O₃ coating absorption in the IR regions, and

(b) eliminating Y₂O₃ coating inhomogeneity.

These two technical roadblocks have been removed by the method disclosed herein that uses a modified reactive plasma ion-assisted deposition method and yttrium metal in an oxygen-containing plasma atmosphere. When the disclosed method is used the absorbance peaks at 3 μm, 6.6 μm and 7.1 μm are not present in an optic having the resulting Y₂O₃ coating. The method can be used to deposit Y₂O₃ coatings having any utilitarian thickness. In one embodiment the deposited Y₂O₃ coatings have a thickness in the range of 300 nm to 3000 nm. In a further embodiment the coating thickness is in the range of 700 nm to 3000 nm. In another embodiment the thickness is in the range of 500 nm to 2000 nm. In an additional embodiment the thickness is in the range of 500 nm to 1200 nm.

FIG. 1 is a graph of transmittance versus wavelength of an uncoated ZnSe substrate, curve 12, used as a reference and a coated ZnSe substrate, curve 10, that was coated according to the prior art using the traditional e-beam evaporation of Y₂O₃ to coat the ZnSe substrate. The Y₂O₃ coating thickness is 600 nm. FIG. 1 shows that the uncoated ZnSe substrate 12 has a transmittance of approximately 70% in the 2-12 μm, but when the substrate is coated using the prior art method there are absorption bands are located at 3.0 μm, 6.6 μm and 7.1 μm, respectively; and that the transmittance loss of the Y₂O₃ coating increases at wavelengths longer than 10.5 μm, falling below the 70% value of the uncoated substrate. As a result, application of Y₂O₃ coatings for these IR optics is restricted.

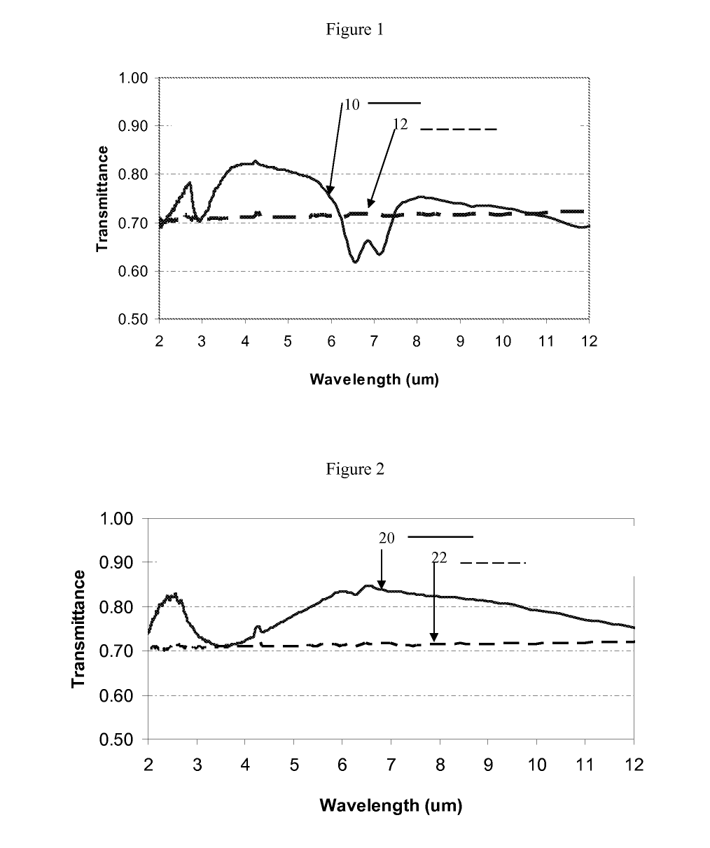

FIG. 2 is a graph of transmittance versus wavelength of an uncoated ZnSe substrate, curve 22, and a ZnSe substrate having a 990 nm thick Y₂O₃ deposited using the yttrium metal and the modified reactive plasma ion-assisted deposition method containing oxygen in the plasma as described herein, curve 20. FIG. 2 also shows that the uncoated ZnSe substrate 22 has a transmittance of approximate 70% in the 2-12 μm range, and that when the substrate is coated using the method described herein the resulting optic has a transmissivity of at least 70% over the entire 2-12 μm wavelength range. The three absorption peaks at 3.0 μm, 6.8 μm and 7.1 μm that were present in FIG. 1 are absent in FIG. 2. In addition, there is a transmittance improvement of the ZnSe/Y₂O₃ optic at wavelengths longer than 10.5 μm. The results shown in FIG. 2 indicate that the first challenge, reducing Y₂O₃ coating absorption in the IR regions,” has been overcome by use of the modified reactive plasma ion-assisted deposition method as described herein.

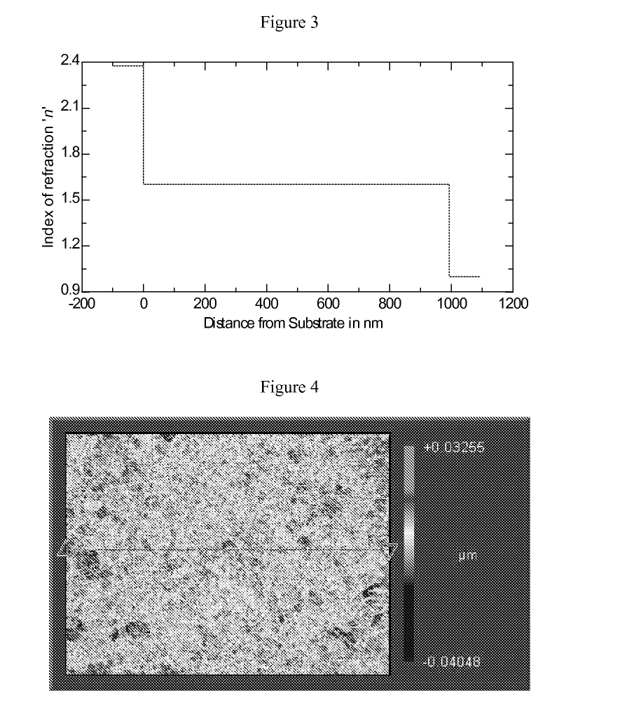

FIG. 3 is a graph of index of refraction versus distance from the substrate at a wavelength of 9 μm for the 990 nm thick Y₂O₃ coating on a ZnSe substrate, the derived Y₂O₃ coating being deposited by use of the modified reactive plasma ion-assisted deposition method. The unique refractive index across the entire coating thickness represents a homogeneous coating structure. The result indicates that the second challenge, “eliminating Y₂O₃ coating inhomogeneity,” has also been overcome and that the 990 nm thick coating deposited on the substrate is homogeneous.

FIG. 4 is a white light interferometry image of the 990 nm-thick Y₂O₃ coating made on a ZnSe substrate using modified reactive plasma ion-assisted deposition. The surface roughness is 6.4 nm measured over a 7.18 mm×5.38 mm area. TT

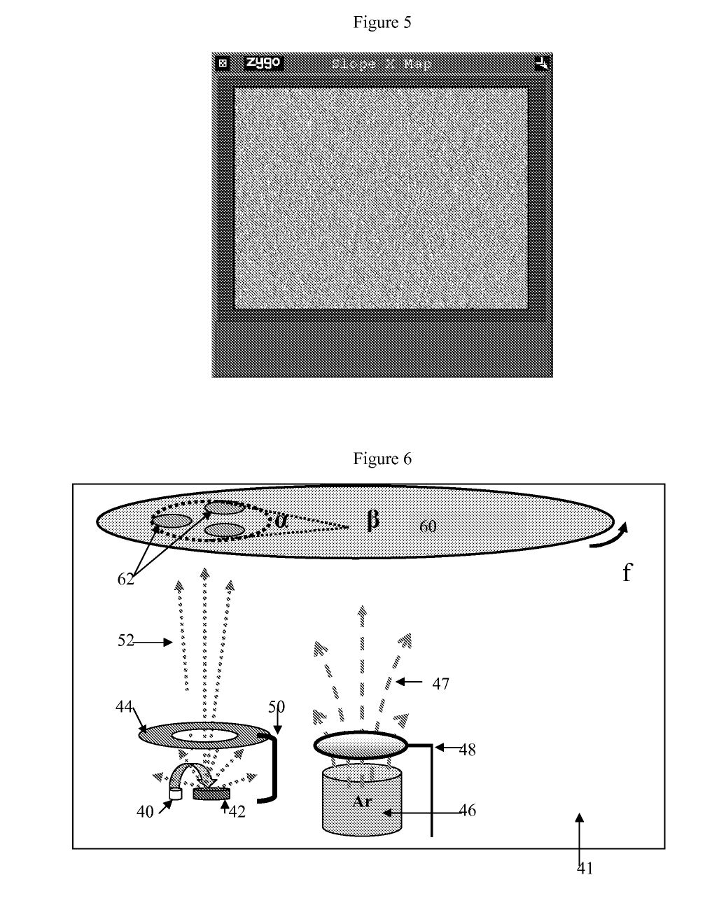

FIG. 5 is a slope map of the white light image of FIG. 4 that clearly shows surface polish structures that are transferred fro the ZnSe substrate to the 990 mm-thick Y₂O₃ surface which indicates a dense and homogeneous film or coating process. The result is consistent with refractive index depth profile shown in FIG. 3.

The results presented in FIGS. 2-4 suggest that a low-loss Y₂O₃ coating has been achieved in which the three absorption peaks at approximately 3.0 μm, 6.6 μm and 7.1 μm in Y₂O₃ coatings have been eliminated by using modified reactive plasma ion-assisted deposition described herein.

FIG. 6 is a schematic drawing of modified reactive PIAD deposition system such as has been described in U.S. Pat. No. 7,465,681, and further including side shield 50 and an O₂ bleed-in source 48 for providing reactive oxygen. The deposition system element shown in FIG. 6 includes a vacuum chamber 41 in which is located at least one substrate 62 on a substrate carrier 60 that rotates at a frequency f, an e-beam 40 that impinges a target 42, for example, a Y target, to produce a vapor flux 52 that passes through an reversed mask 44 for deposition on the substrate 62. There is also a side shield 50 for preventing vaporized Y from being deposited on the top of the plasma source 46 which generates plasma 47. In addition, there is an oxygen, O₂, bleed source 48 for bleeding O₂ into the plasma 47 where it is ionized. The plasma is formed using a noble gas, for example argon. As schematically illustrated in FIG. 6, there are two zones, α and β, where the mechanism of plasma ion interaction with deposition materials significantly differ from each other. In the zone α, the plasma ion bombards the deposition atoms simultaneously and momentum is transferred leading to the formation of a compacted dense layer. Since the plasma contains reactive O ions, there is a reaction between the Y vapor and the O to form Y₂O₃ which is compacted into a dense layer as it is formed. In zone β, the plasma ions continuously collide with the Y₂O₃ deposited on the surface of substrate 62. There is no deposition in zone β, but momentum is transferred to the deposited surface and the presence of O in the plasma insures that the yttrium Y is fully converted to Y₂O₃. The result is a smooth, dense Y₂O₃ coating surface. The overall coating processes can be described by the momentum transfer per deposited atom P as the addition of momentum transfer in zone α (P_{α}) and zone β (P_{β}) in unit of (a.u. eV)^{0.5} during coating process as shown by Equation (1),

$$P = {P}_{α} + {P}_{β} = \frac{1}{2 π} ( \frac{α}{R} κ + \frac{β}{{n}_{s} f} ) {J}_{i} \sqrt{2 {m}_{i} {eV}_{b}} \qquad ( 1 )$$

where Y_{b} is the bias voltage, Jᵢ and mᵢ is the plasma ion flux in ion/(cm² sec) and mass in a.u. (atomic units), respectively. Additionally, R is the deposition rate in nm/sec; e is the electron charge; k is a unit conversion factor; nₛ is the surface atom density of the deposited coating in atom/cm²; and β and α are the radian of the shielded and unshielded areas relative to the center of the rotated plate with a frequency f. By adjusting the reversed mask shape and height, APS (advanced plasma source) parameters and plate rotation frequency, one can separately control the amount of momentum transfer for plasma assisted deposition and for plasma smoothing. Equation (1) can also be used to describe a typical PIAD standard setup, where α and β equal ˜2π and ˜zero, respectively. In this case, the plasma momentum transfer only assists coating deposition, whereas the second term for smoothing is almost zero.

The modified reactive plasma ion-assisted deposition method, which can be used to form Y₂O, includes:

(a) Using high purity yttrium metal as a starting material instead of yttrium oxide for electron-beam evaporation in an oxygen-rich plasma environment. The deposition rate of the Y₂O₃ coating ranges from 0.05 nm/sec to 0.35 nm/sec with an O₂ bleeding rate in the range of 10 sccm to 40 sccm (sccm=standard cubic centimeters per minute).

(b) Using an reversed mask 44 to enable a reactive plasma ion-assisted deposition and an in-situ reactive plasma ion-smoothing in which the reactive plasma ion-assisted deposition and smoothing occur alternatively between a few atomic layers of Y₂O₃ accumulation. The plasma ion-assisted deposition and the in-situ smoothing processes are achieved via plasma ion momentum transfer, adjusted by changing bias voltage between the plasma source and the substrate holder. The bias voltage is in the range of 60V to 150V.

(c) Using a side shield to prevent plasma arcing due to yttrium metal interaction with plasma source insulation components.

(d) Heating the substrate during yttrium evaporation to ensure a completed reactive deposition of Y₂O₃. The substrate heating temperature is in the range of 120° C. to 300° C.

To summarize the method of this disclosure, it is directed to a method for preparing a substrate having a coating of a coating of yttrium oxide thereon that does not have absorption peaks at 3.0 μm, 6.6 μm and 7.1 μm, said method comprising the steps of:

providing a vacuum chamber and within said chamber:

providing a optic on which a coating is to be deposited;

providing a source of yttrium metal and vaporizing said yttrium metal using an e-beam to provide a yttrium vapor flux, said flux passing from said source through a reversed mask to said substrate; providing plasma ions from a plasma source, said plasma ions containing oxygen ions;

rotating said substrate at a selected rotation frequency f;

depositing said coating material on said substrate and bombarding said substrate and said deposited materials with said oxygen ion containing plasma during and after said yttrium deposition process to form a dense, smooth yttrium oxide coating on said substrate;

wherein:

said rotational frequency f is in the range of 12 to 36 rpm, and said flux is delivered to said substrate at an angle φ that is ≦20′; and

the surface of said substrate is bombarded with said plasma ions for a time in the range of 1-4 minutes prior to the deposition of the coating material(s)). The substrate is removed from the coating chamber when the coating process is completed.

The deposition rate of the Y₃O₃ coating is in the range of 0.05 nm/sec to 0.35 nm/sec. The O₂ bleeding rate into the plasma is in the range of 10 sccm to 40 sccm. The plasma ions are formed from a plasma gas, and said plasma gas is selected from the group consisting of argon, xenon, and a mixture of argon or xenon, said gases being mixed with oxygen.

The yttrium oxide coating described herein can be applied to any suitable substrate. In the 2 μm to 12 μm wavelength range suitable substrates include ZnS, ZnSe and Cleartran™ (a special type of multi-spectral ZnS available from Edmund Optics, Barrington, N.J.). The coating can also be used with sapphire substrates, silicon (Si) substrates for 3-5 μm imaging applications, and with germanium substrates (Ge) for both 3-5 μm and 8-12 μm imaging applications.

To summarize the product of this disclosure, the product is an infrared transmissive substrate having a yttrium oxide coating thereon, said coated substrate exhibiting a infrared transmittance equal to or greater than the infrared transmittance of the uncoated substrate over the wavelength range of 2 μm to 12 μm. In one aspect the transmission spectrum of the coated substrate is greater than the transmission spectrum of the uncoated substrate over the wavelength range of 4 μm to 12 μm. In another aspect the transmission spectrum of the coated substrate does not exhibit at least one of the yttrium oxide yttrium oxide infrared absorption peaks at approximately 3.0 μm, 6.6 μm and 7.1 μm within the wavelength range of 2 μm to 12 μm that are found in substrates coated using Y₂O₃ as the starting material for coating. In another aspect the transmission spectrum of the coated substrate does not exhibit at least two of the yttrium oxide yttrium oxide infrared absorption peaks at approximately 3.0 μm, 6.6 μm and 7.1 μm within the wavelength range of 2 μm to 12 μm. In a further aspect the transmission spectrum of the coated substrate does not exhibit the yttrium oxide yttrium oxide infrared absorption peaks at approximately 3.0 μm, 6.6 μm and 7.1 μm within the wavelength range of 2 μm to 12 μm. In an embodiment the yttrium oxide coating has a thickness in the range of 300 nm to 1500 nm. In another embodiment the substrate is selected from the group consisting of ZnS, ZnSe, Cleartran™, Si, Ge and sapphire.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

We claim:

1. An infrared transmissive substrate having a yttrium oxide coating thereon, said coated substrate exhibiting a infrared transmittance equal to or greater than the infrared transmittance of the uncoated substrate over the wavelength range of 2 μm to 12 μm.

2. The yttrium oxide coated substrate according to claim 1, wherein the transmission spectrum of the coated substrate does not exhibit at least one of the yttrium oxide yttrium oxide infrared absorption peaks at approximately 3.0 μm, 6.6 μm and 7.1 μm within the wavelength range of 2 μm to 12 μm.

3. The yttrium oxide coated substrate according to claim 1, wherein the transmission spectrum of the coated substrate does not exhibit at least two of the yttrium oxide yttrium oxide infrared absorption peaks at approximately 3.0 μm, 6.6 μm and 7.1 μm within the wavelength range of 2 μm to 12 μm.

4. The yttrium oxide coated substrate according to claim 1, wherein the yttrium oxide coating has a thickness in the range of 300 nm to 3000 nm.

5. The yttrium oxide coated substrate according to claim 1, wherein the yttrium oxide coating has a thickness in the range of 700 nm to 3000 nm.

6. The yttrium oxide coated substrate according to claim 1, wherein the yttrium oxide coating has a thickness in the range of 500 nm to 2000 nm.

7. The yttrium oxide coated substrate according to claim 1, wherein the yttrium oxide coating has a thickness in the range of 500 nm to 1200 nm.

8. The yttrium oxide coated substrate according to claim 1, wherein the substrate is selected from the group consisting of ZnS, ZnSe, Cleartran™, Si, Ge, sapphire.

9. An infrared transmissive optic having a yttrium oxide coating thereon, said coated substrate exhibiting a infrared transmittance equal to or greater than the infrared transmittance of the uncoated substrate over the wavelength range of 2 μm to 12 μm, and said yttrium oxide coating having a thickness in the range of 300 nm to 3000 nm.

10. The optic according to claim 9, wherein the optic has a yttrium oxide coating thickness in the range of 500 nm to 2000 nm

11. The optic according to claim 9, wherein the transmission spectrum of the coated substrate does not exhibit at least one of the yttrium oxide yttrium oxide infrared absorption peaks at approximately 3.0 μm, 6.6 μm and 7.1 μm within the wavelength range of 2 μm to 12 μm.

12. A method for preparing a substrate having a coating of a coating of yttrium oxide thereon and the coated substrate that does not exhibit at least one of yttrium oxide absorption peaks at 3.0 μm, 6.6 μm and 7.1 μm that are found in substrates coated using Y₂O₃ as the starting material for coating, said method comprising the steps of:
providing a vacuum chamber and within said chamber:
providing a optic on which a coating is to be deposited;
providing a source of yttrium metal and vaporizing said yttrium metal using an e-beam to provide a yttrium vapor flux, said flux passing from said source through a reversed mask to said substrate;
providing plasma ions from a plasma source, said plasma ions containing oxygen ions;
rotating said substrate at a selected rotation frequency f;
depositing said coating material on said substrate and bombarding said substrate and said deposited materials with said oxygen ion containing plasma during and after said yttrium deposition process to form a dense, smooth yttrium oxide coating on said substrate; and
removing
wherein:
said rotational frequency f is in the range of 12 to 36 rpm, and said flux is delivered to said substrate at an angle φ that is ≦20°; and
the surface of said substrate is bombarded with said plasma ions for a time in the range of 1-4 minutes prior to the deposition of the coating martial(s).

13. The method according to claim 8, wherein the deposition rate of the Y₃O₃ coating is in the range of 0.05 nm/sec to 0.35 nm/sec.

14. The method according to claim 8, wherein the O₂ bleeding rate into the plasma is in the range of 10 sccm to 40 sccm.

15. The method according to claim 8, wherein said plasma ions are formed from a plasma gas, said plasma gas is selected from the group consisting of argon, xenon, and a mixture of argon or xenon, said gases being mixed with oxygen.
